(19) United States
(12) Patent Application Publication
(10) Pub. No.: US 2017/0084706 A1
(43) Pub. Date: Mar. 23, 2017

(54) AMORPHIZATION LAYER, SELECTIVE, DEFECT FREE SUPERACTIVATION

(71) Applicant: Applied Materials, Inc., Santa Clara, CA (US)

(72) Inventor: Wolfgang R. ADERHOLD, Cupertino, CA (US)

(21) Appl. No.: 15/263,480

(22) Filed: Sep. 13, 2016

Related U.S. Application Data
(60) Provisional application No. 62/219,853, filed on Sep. 17, 2015.

(51) Int. Cl. H01L 29/417; H01L 21/67; H01L 21/3065; H01L 29/78; H01L 21/324

(52) U.S. Cl. CPC H01L 29/41725; H01L 29/78; H01L 21/324; H01L 21/3065; H01L 21/67069

(57) ABSTRACT

Embodiments of the present disclosure generally relate to superactivation of semiconductor contact layers. In some embodiments, a layer stack includes a source drain layer and a semiconductor contact layer disposed on the source drain layer. A first surface of the semiconductor contact layer contacts the source drain layer. The layer stack further includes a metal layer disposed on the contact layer. A surface of the metal layer contacts a second surface of the semiconductor contact layer. In some embodiments, a method of superactivating a contact layer includes forming a contact layer on a source drain layer, laser pulsing the contact layer at a second contact layer surface, and crystallizing the contact layer to form a crystalline contact layer.

### FIELD

Embodiments of the present disclosure generally relate to superactivation of semiconductor contact layers.

### BACKGROUND

Increased performance of circuit devices including transistors, diodes, resistors, capacitors, and other passive and active electronic devices formed on a semiconductor substrate is typically a major factor considered during design, manufacture, and operation of those devices. For example, during design and manufacture of, metal oxide semiconductor (MOS) transistor semiconductor devices, such as those used in a complementary metal oxide semiconductor (CMOS), it is often desired to minimize the contact resistance. Decreased contact resistance enables higher current from an equal transistor design.

Implantation of dopants into a contact layer results in an amorphous layer with end of range defects that cannot be annealed with a low thermal budget. Furthermore, to melt portions of a layer of a semiconductor substrate, current methods allow for local melting at the point of a contact but energy from the heat source also affects the structural integrity of adjacent semiconductor layers.

Therefore, there is a need in the art to provide semiconductor substrates with improved contact resistance and methods of improving contact resistance of contact layers in semiconductor processing systems.

### SUMMARY

Embodiments of the present disclosure generally relate to superactivation of semiconductor contact layers.

In some embodiments, a layer stack includes a source drain layer and a semiconductor contact layer disposed on the source drain layer. A first surface of the semiconductor contact layer contacts the source drain layer. The layer stack further includes a metal layer disposed on the contact layer. A surface of the metal layer contacts a second surface of the semiconductor contact layer.

In some embodiments, a method of superactivating a contact layer includes forming a contact layer on a source drain layer. The contact layer contacts the source drain layer at a first contact layer surface. The method further includes laser pulsing the contact layer at a second contact layer surface. The laser pulsing melts a portion of the contact layer. The method further includes crystallizing the contact layer to form a crystalline contact layer.

### BRIEF DESCRIPTION OF THE DRAWINGS

Embodiments of the present disclosure, briefly summarized above and discussed in greater detail below, can be understood by reference to the illustrative embodiments of the present disclosure depicted in the appended drawings. It is to be noted, however, that the appended drawings illustrate only typical embodiments of the present disclosure and are therefore not to be considered limiting of its scope, for the present disclosure may admit to other equally effective embodiments.

FIGS. 1A-1F illustrate cross-sectional views of a substrate at different stages of integrated circuit fabrication sequence incorporating a superactivated contact layer, according to some embodiments.

FIG. 2 illustrates a cross-sectional view of a PECVD chamber, according to some embodiments.

FIG. 3 is a schematic side view of a system for laser processing of substrates, according to some embodiments.

FIG. 4 illustrates a cross-sectional view of a substrate containing more than one S/D region of different material compositions, according to some embodiments.

FIGS. 5A-5B illustrate cross-sectional views of a substrate containing a P-doped contact layer and an N-doped contact layer, according to some embodiments.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

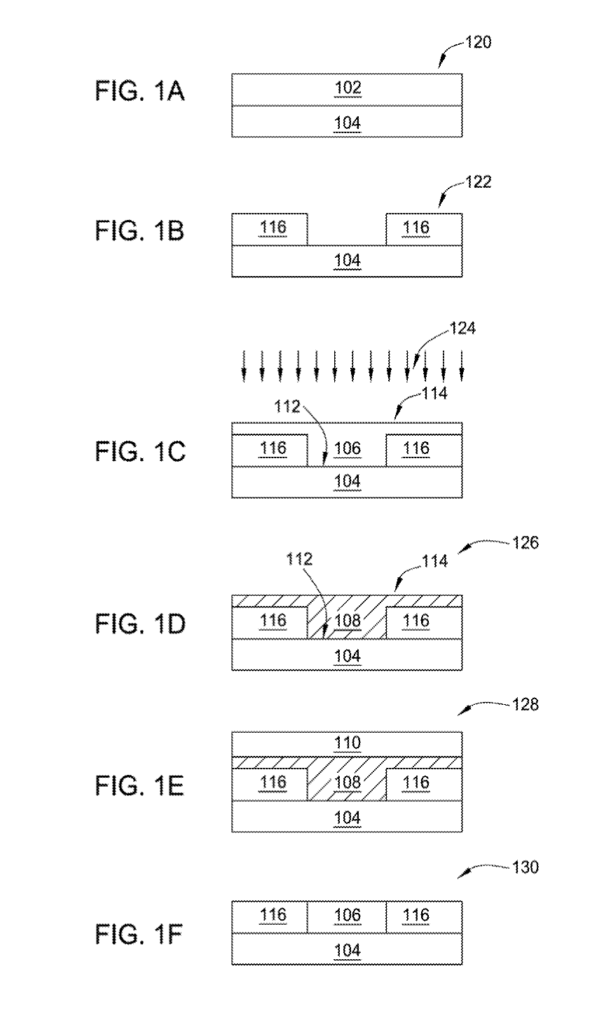

The present disclosure generally relates to superactivation of semiconductor contact layers. FIGS. 1A-1F illustrate cross-sectional views of a substrate at different stages of integrated circuit fabrication sequence incorporating a superactivated contact layer. As shown in FIG. 1A, substrate 120 comprises a field isolation dielectric layer 102 disposed on a source drain (S/D) layer 104. Field isolation dielectric layer 102 may be SiO₂. Field isolation dielectric layer 102 may be formed by CVD deposition of SiO₂ onto S/D layer 104, followed by patterning field isolation dielectric layer 102 down to the S/D layer 104 to form patterned field isolation dielectric layer 116 of substrate 122, as shown in FIG. 1 B. Patterning field isolation layer 102 may be accomplished by any suitable patterning process, such as photolithography. Photolithography may be accomplished by the CENTURA® TETRA™ supplied by Applied Materials, Inc. of Santa Clara, Calif.

As shown in FIG. 1C, substrate 124 comprises an amorphous contact layer 106 disposed on field isolation dielectric layer 116 and an exposed portion of S/D layer 104. Amorphous contact layer 106 may be etched to a desired thickness and/or to expose field isolation dielectric layer 116. Amorphous contact layer 106 may also be selectively deposited epitaxially such that amorphous contact layer 106 is present in a via of field isolation dielectric layer 116 while the top surfaces of field isolation dielectric layer 116 remain exposed, i.e. little or no deposition of amorphous contact layer 106 on the top surfaces of field isolation dielectric layer 116. FIG. 1F is a cross-sectional view of a s/d layer 104 with field isolation dielectric layer 116 and an amorphous contact layer 106 selectively deposited in a via.

Amorphous contact layer 106 may be annealed, as described in more detail below, to form superactivated contact layer 108 of substrate 126, as shown in FIG. 1D. As shown in FIG. 1E, substrate 128 may have a metal contact layer 110 disposed on superactivated contact layer 108. If top surfaces of field isolation dielectric layer 116 are exposed, metal contact layer 110 may be disposed on both superactivated contact layer 108 and the field isolation dielectric layer 116.

### Exemplary Chamber Hardware

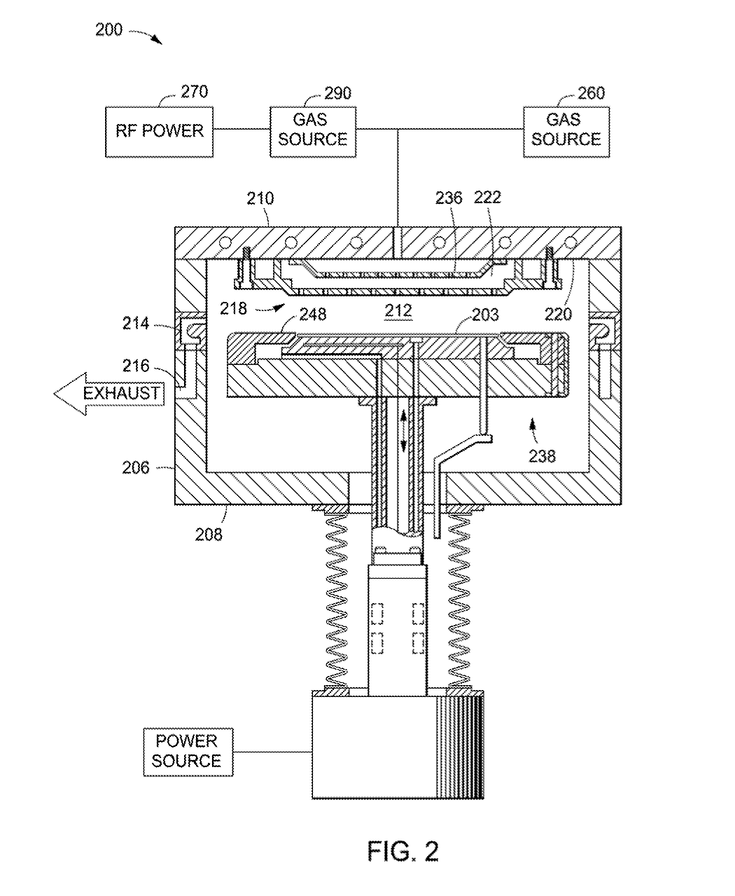

In some embodiments, field isolation dielectric layer 102 and amorphous contact layer 106 are deposited in a PECVD chamber, such as the PECVD chamber 200 shown in FIG. 2. As shown in FIG. 2, the process chamber 200 includes walls 206, a bottom 208, and a lid 210 that define a process volume 212. A substrate support assembly 238, which may be heated, may be centrally disposed within the process chamber 200. The substrate support assembly 238 supports a substrate 203 during a deposition process.

The substrate support assembly 238 additionally supports a circumscribing shadow ring 248. The shadow ring 248 is annular in form and typically comprises a ceramic material such as, for example, aluminum nitride. Generally, the shadow ring 248 prevents deposition at the edge of the substrate 203 and substrate support assembly 238.

A showerhead 218 may generally be coupled to an interior side 220 of the lid 210. A perforated blocker plate 236 may optionally be disposed in the space 222 between the showerhead 218 and lid 210. Gases (i.e., process and other gases) that enter the process chamber 200 through the mixing block are first diffused by the blocker plate 236 as the gases fill the space 222 behind the showerhead 218. The gases then pass through the showerhead 218 and into the process chamber 200. The blocker plate 236 and the showerhead 218 are configured to provide a uniform flow of gases to the process chamber 200. Uniform gas flow is desirable to promote uniform layer formation on the substrate 203. During the deposition process of, for example, field isolation dielectric layer 102 or amorphous contact layer 106, the distance between the substrate 203 and the showerhead 218 may be between about 320 mm and about 580 mm. A gas source 260 is coupled to the lid 210 to provide gas through gas passages in the showerhead 218 to a processing area between the showerhead 218 and the substrate 203. An RF source 270 is coupled through a match network 290 to the lid 210 and/or to the showerhead 218 to provide an RF current to the showerhead 218.

The PECVD process chamber 200 of FIG. 2 may be used to deposit field isolation dielectric layer 102, S/D layer 104, amorphous contact layer 106, and/or metal contact layer 110. Alternatively, one or more of field isolation layer 102, S/D layer 104, amorphous contact layer 106, and metal contact layer 110 may be deposited using any suitable physical vapor deposition (PVD) chamber, such as an ENDURA® Al PVD chamber supplied by Applied Materials, Inc. of Santa Clara, Calif.

In some embodiments, a plasma is formed using an RF power ranging from about 300 W to about 600 W at an RF frequency of 13.56 MHz, while the substrate, such as S/D layer 104, structure is maintained at a temperature below 450° C., such as at 420° C. The RF power may be adjusted to fine tune the film stress. The processing pressure in the processing region is normally maintained at between about 3 Torr and about 4.2 Torr. In some embodiments, the plasma contains a processing gas mixture for depositing, for example, a P-doped SiGe amorphous contact layer 106, including a silicon containing gas, a germanium containing gas, a boron containing gas and hydrogen gas. In some embodiments, the germanium containing gas and the boron containing gas are pre-mixed with the hydrogen gas in the gas cylinder. In some embodiments, the silicon containing gas is silane (SiH₄), the germanium containing gas is germane (GeH₄), and the boron containing gas is diborane (B₂H₆). In some embodiments, the silicon containing gas has a flow rate between about 0.01 sccm/cm² and about 0.5 sccm/cm², about 0.02 sccm/cm² and about 0.4 sccm/cm², about 0.064 sccm/cm² and about 0.282 sccm/cm². The germanium containing gas has a flow rate between about 0.01 sccm/cm² and about 2 sccm/cm², about 0.03 sccm/cm² and about 1.7 sccm/cm², about 0.354 sccm/cm² and about 1.414 sccm/cm². The hydrogen gas has a flow rate between about 0.01 sccm/cm² and about 12 sccm/cm², about 4 sccm/cm² and about 9 sccm/cm², about 5.941 sccm/cm² and about 7.779 sccm/cm². Boron containing gas has a flow rate between about 0.01 sccm/cm² and about 0.5 sccm/cm², about 0.03 sccm/cm² and about 0.3 sccm/cm², about 0.064 sccm/cm² and about 0.212 sccm/cm². The flow rates are per each square centimeter of the surface area of the substrate or substrates so the total flow for any size substrate is readily determined. In some embodiments, a deposition process lasts between about 50 seconds and about 1000 seconds, forming a layer, such as field isolation dielectric layer 102 or amorphous contact layer 106, the layer having a thickness between about 0.1 micrometers and about 10 micrometers. In some embodiments, the deposited layer has a thickness of greater than or equal to about 10 micrometers.

A variety of process gas mixtures may be used in the deposition process. Process gases for deposition of S/D layer 104 and amorphous contact layer 106 include silane (SiH₄) and germane (GeH₄). Alternatively or additionally, S/D layer 104 and/or amorphous contact layer 106 may comprise a group III-V material formed from any suitable process gases. Group III-V material includes indium, tin, titanium, aluminum, gallium, arsenic, combinations thereof and oxides thereof.

Process gases for deposition of field isolation dielectric layer 102 may be an organosilicon compound in combination with an oxidizing gas. Suitable organosilicon compounds may be siloxane compounds, such as triethoxysiloxane, tetramethoxysiloxane, trimethoxysiloxane, hexamethoxy-disiloxane, octamethoxytrisiloxane, and/or octamethoxydodecasiloxane, silazoxane compounds having one or more nitrogen groups, hexamethoxydisilazoxane, methyl hexamethoxydisilazoxane, chlorohexamethoxydisilazoxane, hexaethoxy-disilazoxane, nonamethoxytrisilazoxane, and octamethoxycyclosilazoxane, halogenated siloxane compounds that include one or more halogen moieties (e.g., fluoride, chloride, bromide, or iodide), such as tetrachlorosilane, dichlorodiethoxysiloxane, chlorotriethoxysiloxane, hexachlorodisiloxane, and/or octachlorotrisiloxane, and aminosilanes, such as trisilylamine, hexamethyldisilazane, silatrane, tetrakis(dimethylamino)silane, bis(diethylamino)silane, tris(dimethyl-amino)chlorosilane, and methylsilatrane. Suitable organosilicon compounds may also be disilanes, such as alkoxy disilanes, alkoxy-alkyl disilanes, and alkoxy-acetoxy disilanes, including compounds having the general structure:

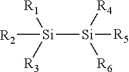

wherein R₁-R₆ may be, independently, a C₁₋₃ alkoxy group, a C₁₋₃ alkyl group, or an acetoxy group, wherein at least one of R₁₋₆ is an alkoxy group or an acetoxy group. Suitable organosilicon compounds also include cyclic disilanes with alkyl and alkoxy moieties, such as butasilanes, pentasilanes, hexasilanes, heptasilanes, octasilanes, and the like, having at least one alky and alkoxy group. Examples include octamethyl-1,4-dioxa-2,3,5,6-tetrasilacyclohexane, 1,4-dioxa-2,3,5,6-tetrasilzcyclo-hexane; and 1,2,3,4,5,6-hexamethoxy-1,2,3,4,5,6-hexamethylcyclohexasilane, among other alkoxy-alkylcyclosilanes. Suitable organosilicon compounds also include organocyclosilanes such as cyclobutasilane, cyclopentasilane, cyclohexasilane, cycloheptasilane, cyclooctasilane, and other similar compounds. Suitable oxidizing gases include oxygen (O₂), ozone (O₃), nitrous oxide (N₂O), carbon monoxide (CO), carbon dioxide (CO₂), and combinations thereof.

The metal layer 110 may be, or include, titanium, cobalt, nickel, Si alloys thereof, and mixtures thereof.

One or more of S/D layer 104, field isolation layer 102, and contact layer 106 may be P-doped or N-doped. Doped layers may be achieved by doping an as-deposited layer and/or doping in-situ as the layer is deposited. P-doping of a layer may be carried out using a boron containing gas as one of the gas sources of PECVD process chamber 200. Boron containing gases include borane, diborane, triborane, trimethylborane, triethylborane, and mixtures thereof. Other P-type dopants include atomic or molecular aluminum, atomic or molecular nitrogen, atomic or molecular gallium, atomic or molecular indium, and combinations thereof. N-doping of a layer may be carried out using atomic or molecular phosphorous (such as phosphine), atomic or molecular arsenic, atomic or molecular antimony, atomic or molecular bismuth, atomic or molecular lithium, and combinations thereof, as one of the gas sources of PECVD process chamber 200. In some embodiments, the concentration of dopant in a layer is between about 10¹⁵ atoms/cm³ to about 10²¹ atoms/cm³.

### Exemplary Annealing Hardware

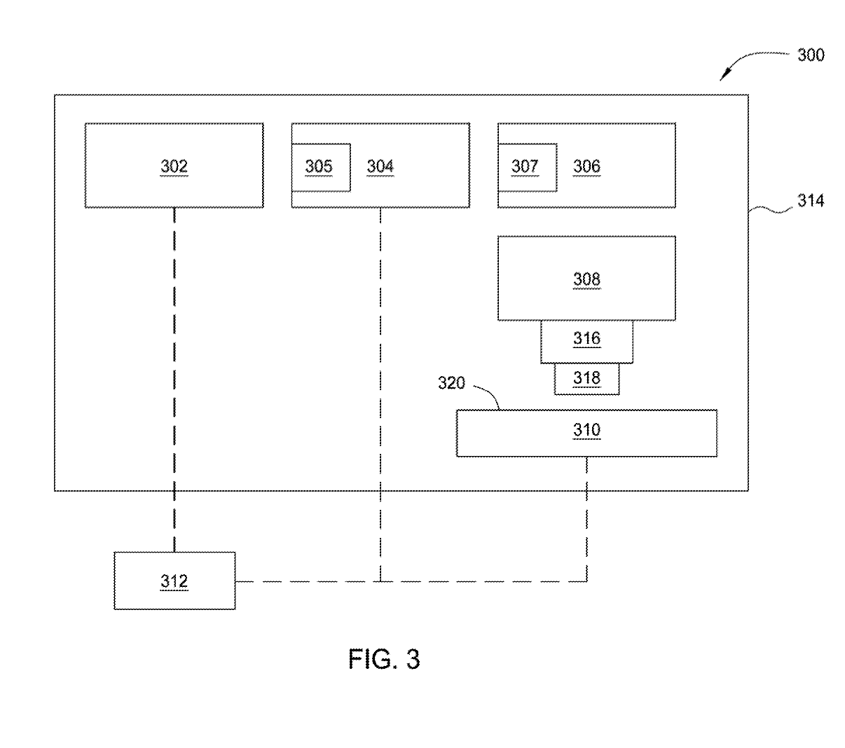

FIG. 3 is a perspective view of a system 300 for laser processing of substrates according to some embodiments of the present disclosure. Amorphous contact layer 106 of FIG. 10 may be laser annealed using system 300 to form superactivated contact layer 108 of FIG. 1D. System 300 comprises an energy module 302 that has a plurality of pulsed laser sources producing a plurality of laser pulses. Pulse control module 304 is configured to combine individual laser pulses into combination laser pulses, and control intensity, frequency characteristics, and polarity characteristics of the combination pulsed laser pulses. A pulse shaping module 306 is configured to adjust the temporal profile of a laser pulse. One or more pulses exit the pulse control module 304 and enter the pulse shaping module 306, which has one or more pulse shapers 307. Pulse shaper 307 may comprise a plurality of mirrors and a plurality of splitters that are used to delay portions of a laser energy pulse to provide a composite pulse that has desirable characteristics (e.g., pulse width and profile). Homogenizer 308 is configured to adjust the spatial energy distribution of a laser pulse, overlapping the combination pulsed laser pulses into a single uniform energy field. System 300 further comprises an aperture member 316 that removes residual edge non-uniformity from the energy field, and an alignment module 318 that allows precision alignment of the laser energy field with a substrate disposed on a substrate support 310. Alignment module 318 receives a shaped, smoothed, and truncated energy field from the aperture member 316 and projects it onto a substrate disposed on a work surface 320 of the substrate support 310.

A controller 312 is coupled to the energy module 302 to control production of the laser pulses, the pulse control module 304 to control pulse characteristics, and the substrate support 310 to control movement of the substrate with respect to the energy field. An enclosure 314 encloses the operative components of the system 300. The lasers may be any type of laser capable of forming short pulses, for example duration less than about 100 nsec., of laser radiation. In some embodiments, high modality lasers having over 500 spatial modes with M² greater than about 30 are used. Solid state lasers such as Nd:YAG, Nd:glass, titanium-sapphire, or other rare earth doped crystal lasers are frequently used, but gas lasers such as excimer lasers, for example XeCl₂, ArF, or KrF lasers, may be used. The lasers may be switched, for example by q-switching (passive or active), gain switching, or mode locking. A Pockels cell may also be used proximate the output of a laser to form pulses by interrupting a beam emitted by the laser. The lasers may have wavelength between about 200 nm and about 2,000 nm, such as between about 400 nm and about 1,000 nm, such as about 510 nm to about 540 nm, for example about 532 nm. In some embodiments, the lasers are q-switched frequency-doubled Nd:YAG lasers. The lasers may all operate at the same wavelength, or one or more of the lasers may operate at different wavelengths from the other lasers in the energy module 302. The lasers may be amplified to develop the power levels desired. In most cases, the amplification medium will be the same or similar composition to the lasing medium. Each individual laser pulse is usually amplified by itself, but in some embodiments, all laser pulses may be amplified after combining.

A laser pulse delivered to a contact layer may be a combination of multiple laser pulses. The multiple pulses are generated at controlled times and in controlled relationship to each other such that, when combined, a single pulse of laser radiation results that has a controlled temporal and spatial energy profile, with a controlled energy rise, duration, and decay, and a controlled spatial distribution of energy non-uniformity. The plurality of lasers are arranged so that each laser produces pulses that emerge into the pulse control module 304, which may have one or more pulse controllers 305. The controller 312 may have a pulse generator, for example an electronic timer coupled to a voltage source, that is coupled to each laser, for example each switch of each laser, to control generation of pulses from each laser.

The annealing apparatus may be an annealing apparatus such as any suitable annealing apparatus, such as Astra™ or Vulcan™, supplied by Applied Materials, Inc. of Santa Clara, Calif.

After deposition of amorphous contact layer 106, amorphous contact layer 106 may be subjected to laser annealing by, for example, system 300. Laser annealing of amorphous contact layer 106 melts at least a portion of contact layer 106 and, upon cooling, transitions amorphous contact layer 106 (of FIG. 10) into a superactivated (crystalline) contact layer 108 (of FIG. 1D). In some embodiments, melting at least a portion of contact layer 106 includes melting the entire contact layer 106. Laser pulses for contact layer annealing may be chosen to reduce/eliminate thermal load on adjacent gate structures and S/D layers. Laser pulses may be of short duration, for example, between about 0.1 nsec. to about 100 nsec. In some embodiments, pulse power levels are between about 10 mJ/cm² to about 500 mJ/cm², such as about 100 mJ/cm² to about 200 mJ/cm². Annealing temperatures (e.g., the temperature of contact layer 106) may be between about 200° C. to about 2,000° C., such as about 1400° C. to about 1600° C. In some embodiments, 1400° C. promotes melting of amorphous SiGe while 1600° C. promotes melting of crystalline silicon. In some embodiments, the annealing apparatus provides at least about 90% energy density uniformity and at least about 90% contact layer temperature uniformity across a contact layer.

Annealing may consist of a single pulse due to a first pulse that is sufficient to melt contact layer 106. In some embodiments, a complete melt of contact layer 106 is preferred because the melted contact layer reflects additional laser pulse energy better than the same contact layer at a sub-melt temperature. However, excess irradiation may promote thermal load increase to adjacent semiconductor layers, for example sub-melt/melt temperatures of field isolation layer 116, highlighting an advantage of processing parameters described herein. Furthermore, the annealing described herein results in a contact layer having minimal or no defects.

Amorphous layers generally possess a lower melt point than adjacent crystalline layers. Laser annealing as described herein allows for controlled and rapid thermal processing to reduce/prevent diffusion of heat as well as dopant(s) into adjacent layers. Furthermore, if S/D layer 104, for example, absorbs heat from a laser pulse, S/D layer 104 may partially melt which gives a reduction in strain. Melting of predominantly, if not exclusively, amorphous contact layer 106, with laser annealing described herein preserves strain in S/D layer 104.

In some embodiments, amorphous contact layer 106 and S/D layer 104 comprise the same material. If amorphous contact layer 106 and S/D layer 104 are the same material, the crystallinity of laser annealed contact layer 106 (to form superactivated contact layer 108) is more likely to be similar to, e.g. match, the crystallinity of S/D layer 104 than if contact layer 106 and S/D layer 104 are not the same material. For example, a SiGe50% S/D layer 104 promotes crystallization of a laser annealed SiGe50% contact layer 106.

Furthermore, laser annealing an amorphous contact layer 106 containing more than one material in the layer may take advantage of a “segregation effect”, where the concentration of a first material after laser annealing and crystallization of a contact layer is greater at a first surface of the contact layer than a concentration of the first material at a second surface of the contact layer. For example, in embodiments where amorphous contact layer 106 is SiGe, laser melt of amorphous contact layer 106 promotes a higher Ge content at a second surface 114 of the superactivated contact layer 108 upon crystallization than Ge content at a first surface 112 due to the segregation effect. Accordingly, the Ge and Si concentrations form a first concentration gradient and a second concentration gradient, respectively, across the superactivated contact layer 108 from second surface 114 to first surface 112. Annealing (melting) for longer time periods or with additional laser pulses may increase the Ge content at second surface 114 of the contact layer. In some embodiments, annealing at sub-melt temperatures does not promote segregation of a contact layer, such as a SiGe layer. Furthermore, a longer wavelength laser and short pulse durations promote the segregation effect better than a short wavelength laser, with for example silicon-on-insulator structures and Gate All Around structures.

In some embodiments, a contact layer having a concentration gradient is advantageous because a first material, such as Ge, has a better contact property than a second material, such as Si, towards a metal contact layer 110, such as Ti. After crystallization and segregation of an amorphous contact layer 106 that is, for example, SiGe (to form a superactivated contact layer 108 that is SiGe), the higher Ge content at second surface 114 of the SiGe superactivated contact layer 108 improves contact resistance between second surface 114 of SiGe superactivated contact layer 108 and subsequently deposited metal contact layer 110, as compared to a contact layer that is predominantly (if not exclusively) Si.

The weight % of a first material, such as Ge, in a contact layer (that also contains a second material, such as Si) may be between about 1% to about 99%, such as about 20% to about 70%, such as about 40% to about 60%, for example about 50%. For example, in embodiments where amorphous contact layer 106 is SiGe50%, segregation upon annealing as described herein yields superactivated contact layer 108 having an about 75% Ge content at second surface 114, when the source drain layer is also SiGe50%.

In some embodiments, laser annealing an amorphous contact layer 106 containing P-dopant(s) and/or N-dopant(s) may similarly take advantage of a “segregation effect”, where the concentration of one or more dopants after laser annealing and crystallization of amorphous contact layer 106 is greater at second surface 114 of the superactivated contact layer 108 than a concentration of the one or more dopants at first surface 112 of superactivated contact layer 108.

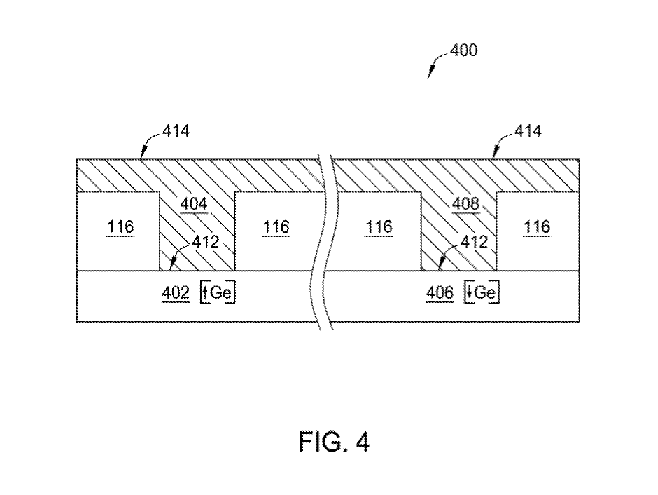

FIG. 4 illustrates a cross-sectional view of a substrate 400 containing more than one S/D region of different material compositions. As shown in FIG. 4, a first S/D layer 402 is disposed adjacent a first superactivated contact layer 404 and has a higher Ge concentration than a second S/D layer 406. Second S/D layer 406 is disposed adjacent a second superactivated contact layer 408. First S/D layer 402 and first superactivated contact layer 404 may be spaced apart from second S/D layer 406 and second superactivated contact layer 408 by a distance of between about 100 nm to about 200 nm, for example about 150 nm. Any suitable gate stack (not shown) may be formed within the distance between first S/D layer 402/first superactivated contact layer 404 and second S/D layer 406/second superactivated contact layer 408. In some embodiments where first superactivated contact layer 404 and second superactivated contact layer 408 have substantially similar or the same concentration of material, such as Ge and Si, the higher Ge concentration of the first S/D layer 402 promotes a higher Ge concentration at first surface 412 of the first superactivated contact layer 404 than the Ge concentration at the second surface 414, as compared to the Si and Ge concentration gradient of the second superactivated contact layer 408. The second superactivated contact layer 408 may have a higher Ge concentration at the second surface 414 and a higher Si content at the first surface 412 than that of the first superactivated contact layer 404 because of the lower Ge concentration of second S/D layer 406 as compared to the Ge concentration of first S/D layer 402. Therefore, in some embodiments, the concentration of the material of a source drain layer may affect the concentration gradient of an adjacent superactivated contact layer, and, because of this, may also affect the contact resistance of a contact layer disposed adjacent a metal layer.

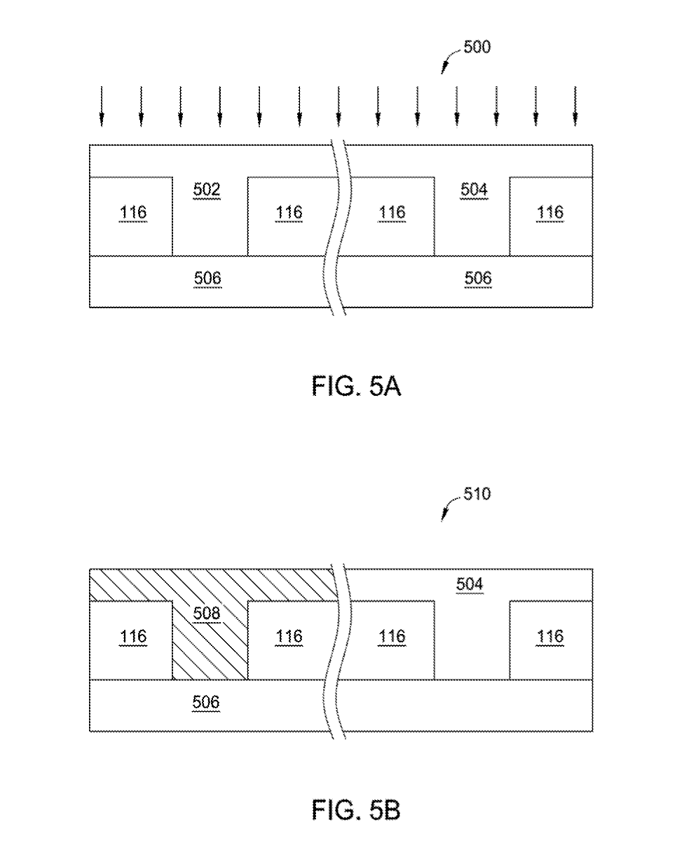

FIGS. 5A-5B illustrate cross-sectional views of a substrate 500 containing a P-doped contact layer and an N-doped contact layer. As shown in FIG. 5A, a P-doped amorphous contact layer 502 and an N-doped amorphous contact layer 504 are each disposed adjacent to S/D layer 506. P-doped amorphous contact layer 502 and N-doped amorphous contact layer 504 may be spaced apart from each other by a distance of between about 100 nm to about 200 nm, for example about 150 nm. Any suitable gate stack (not shown) may be formed within the distance between P-doped amorphous contact layer 502 and N-doped amorphous contact layer 504. In embodiments where P-doped amorphous contact layer 502 and N-doped amorphous contact layer 504 have substantially similar or the same concentration of, for example, Ge and Si, P-doped amorphous contact layer 502 may have different properties, such as melting point, than N-doped amorphous contact layer 504 because of the presence of the dopants in the layers. Methods and apparatus described herein (e.g., pulse parameters) allow selective melting of, for example, P-doped amorphous contact layer 502 into P-doped superactivated contact layer 508 (of FIG. 5B) without affecting structural integrity (e.g., by melting) of N-doped amorphous contact layer 504. Accordingly, a doped layer having different properties, such as lower melting point, than another doped layer of the substrate allows for selective superactivation of contact layers of the substrate.

Overall, apparatus and methods described herein provide laser pulses for contact layer annealing that reduce/eliminate thermal load on adjacent gate structures, field isolation layers, and S/D layers, which preserves strain of the adjacent gate structures and other layers. Apparatus and methods described herein further provide controlled and rapid thermal processing to reduce/prevent diffusion of heat as well as dopant(s) into adjacent gate structures and other layers. Methods described herein result in a contact layer having minimal or no defects. In embodiments where a contact layer comprises more than one material, methods described herein result in a contact layer having a concentration gradient from a first surface of the contact layer to a second surface of the contact layer. A concentration gradient promotes improved contact resistance between a superactivated contact layer and an adjacent metal layer. Methods described herein further provide for selective superactivation of contact layers of the substrate.

While the foregoing is directed to embodiments of the present disclosure, other and further embodiments of the present disclosure may be devised without departing from the basic scope thereof.

1. A layer stack comprising:
a source drain layer;
a semiconductor contact layer disposed on the source drain layer, wherein a first surface of the semiconductor contact layer contacts the source drain layer; and
a metal layer disposed on the semiconductor contact layer, wherein a surface of the metal layer contacts a second surface of the semiconductor contact layer.

2. The layer stack of claim 1, further comprising:
a field isolation dielectric layer disposed on the source drain layer, wherein a first surface of the field isolation dielectric layer contacts the source drain layer and a second surface of the field isolation dielectric layer contacts a third surface of the semiconductor contact layer.

3. The layer stack of claim 1, wherein the semiconductor contact layer comprises silicon, germanium, or a group III-V material.

4. The layer stack of claim 3, wherein the semiconductor contact layer is germanium.

5. The layer stack of claim 1, wherein the semiconductor contact layer consists of a first material and a second material, wherein the first material is silicon and the second material is germanium or a group III-V material.

6. The layer stack of claim 5, wherein the second material is germanium.

7. The layer stack of claim 1, wherein the source drain layer comprises a material selected from the group consisting of silicon, germanium, and a group III-V material.

8. The layer stack of claim 7, wherein the source drain layer comprises a first material and a second material, wherein the first material is silicon and the second material is germanium or a group III-V material.

9. The layer stack of claim 8, wherein the first material of each of the semiconductor contact layer and the source drain layer is silicon and the second material of each of the semiconductor contact layer and the source drain is germanium.

10. The layer stack of claim 1, wherein the semiconductor contact layer has a concentration gradient, wherein the concentration of a first material of the semiconductor contact layer at the first surface of the semiconductor contact layer is greater than the concentration of the first material at the second surface of the semiconductor contact layer, and wherein the concentration of a second material of the semiconductor contact layer at the first surface of the semiconductor contact layer is less than the concentration of the second material at the second surface of the semiconductor contact layer.

11. The layer stack of claim 1, wherein the semiconductor contact layer comprises a first material and a second material, wherein the first material has a wt % between about 40% to about 60% of total weight of the semiconductor contact layer.

12. The layer stack of claim 1, wherein the semiconductor contact layer is doped and a dopant is selected from the group consisting of borane, diborane, triborane, trimethylborane, triethylborane, and mixtures thereof.

13. The layer stack of claim 1, wherein the semiconductor contact layer is doped and a dopant is phosphine or arsine.

14. The layer stack of claim 1, wherein the metal layer is selected from the group consisting of titanium, cobalt, nickel, silicon alloys thereof, and mixtures thereof.

15. A method of superactivating a contact layer, comprising:
forming a contact layer on a source drain layer, wherein the contact layer contacts the source drain layer at a first contact layer surface;
laser pulsing the contact layer at a second contact layer surface, wherein the laser pulsing melts a portion of the contact layer; and
crystallizing the contact layer to form a crystalline contact layer.

16. The method of claim 15, wherein the laser pulsing is performed using a laser pulse duration between about 0.1 nsec. to about 100 nsec.

17. The method of claim 15, wherein the laser pulsing is performed using laser pulse power levels between about 100 mJ/cm² to about 200 mJ/cm².

18. The method of claim 15, wherein the laser pulsing heats the contact layer to a temperature between about 1400° C. to about 1600° C.

19. The method of claim 15, wherein the laser pulsing is performed using a laser pulse wavelength between about 400 nm to about 1,000 nm.

20. The method of claim 19, wherein the laser pulsing is performed using a laser pulse wavelength between about 510 nm to about 540 nm.
